(19) United States
(12) Patent Application Publication
(10) Pub. No.: US 2008/0217749 A1
(43) Pub. Date: Sep. 11, 2008

(54) Low Capacitance Transient Voltage Suppressor

(76) Inventors: Fred Matteson, Phoenix, AZ (US); Rakesh Kansal, Scottsdale, AZ (US)

Correspondence Address: WILLIAM C. CAHILL, 155 PARK ONE, 2141 E. HIGHLAND AVENUE, PHOENIX, AZ, 85016, US

(21) Appl. No.: 11/996,678

(22) PCT Filed: Jul. 27, 2006
(86) PCT No.: PCT/US2006/029232

§ 371 Date: May 15, 2008

Related U.S. Application Data
(60) Provisional application No. 60/702,867, filed on Jul. 27, 2005.

(51) Int. Cl. H01L 29/868

(52) U.S. Cl. 257/656; 257/E29.336

(57) ABSTRACT

A transient voltage suppressor includes a reverse bias transient voltage suppressor PN diode connected in series with a forward biased PIN diode, the series circuit formed by the PN diode and the PIN diode is connected between first and second terminals and in parallel with a reverse biased PIN diode.

### FIELD OF THE INVENTION

This invention is in the field of solid state device circuits and particularly in the field of diode based transient voltage suppressor circuits

### BACKGROUND

The PN diode where a P-type impurity is incorporated into semiconductor material along with N-type impurity remains an important device. A P-type impurity is one where there is an excess of holes or what are treated as positive, mobile charges hence the P for positive while an N-type impurity is where there are an excess of negative, mobile charges hence the N for negative. The key to the electrical performance of the PN diode is the junction where the P-type and N-type impurities are the same concentration in the semiconductor material. At either side of this point the semiconductor material is either P-type or N-type. This structure can be realized in many ways but in every case the PN diode has very similar current-voltage characteristics. In a forward-biased condition where an outside voltage in placed on the PN diode the diode readily conducts current while in the reversed bias mode the diode conducts very low currents until a particular voltage known as the breakdown voltage is reached where the diode again begins to conduct high values of current. This breakdown voltage is a critical point since the PN diode is operating at both high voltage and high current, it is experiencing high power and therefore could be destroyed if such high power conditions lasted for a substantial period of time. The breakdown voltage is considered as a key maximum rating for a PN diode, as is the maximum sustained power and the maximum current in the forward biased condition.

PN diodes make good rectifiers where they are used to convert AC voltage into DC voltage. This feature of PN diodes is vital for such products as: automotive alternators, battery chargers for portable equipment and power supplies for all types of electronic systems.

The key semiconductor material used in PN diodes is silicon, which can be processed to yield a variety of PN diodes each optimized for a particular application. One such application that was needed early on was transient voltage suppressor since high voltage spikes could severely damage or destroy electronic systems. This problem was noted early on in telephone systems, which were hit by lightening strikes causing the damaging voltage spikes. What was needed was a device, which could be placed across the input of the electronic devices that would turn on when a certain voltage level was exceeded and divert that high voltage and the resulting energy through this protective device, which was labeled a transient voltage suppressor.

The transient voltage suppressor used the breakdown voltage characteristic of the PN diode to provide the protective function required by the electronics industry. Special processing of the PN diodes achieved devices that had a controlled breakdown voltage at a level that was low enough in value to protect more sensitive solid state electronic devices while at the same time these special PN diodes were able to safely dissipate the power associated with the high voltage spike. As solid state electronics evolved getting faster, smaller and operating at lower voltage levels, problems with voltage transients increased. Now along with problems of surges in the power lines due to a variety of causes, the solid-state electronic devices had problems with electro-static discharge again due to a variety of causes, but often associated with handling of the electronic device or system. An entire family of transient voltage suppressors housed in a number of different packages and having differing electrical characteristics has now been established to address the variety of needs for protection of sensitive electronics for voltage transients.

One electrical characteristic that created challenges for the makers of transient voltage suppressors is the capacitance associated with the suppressor, which caused problems in the system in which the suppressor was installed. It is difficult to reduce the capacitance of a transient voltage suppressor PN diode since that capacitance is related directly to the active area of the PN diode. That active area is directly related to the amount of power that the transient voltage suppressor can dissipate which of course is a critical parameter in the use of that transient voltage suppressor. In order to reduce the capacitance of the transient voltage suppressor, the makers modified the suppressor by adding a PN diode rectifier to the transient voltage suppressor PN diode. This addition took advantage of the fact that two separate capacitances in series act to reduce the overall capacitance according to well-known equations. An example of such a circuit can be seen in U.S. Pat. No. 3,372,285. As can be seen the two PN diodes are connected in a back-to-back configuration across two circuit lines such that one diode could conduct current flowing in one direction easily but the other serves to block that current since it is reversed biased. The only time this two PN diode circuit conducts current easily is when a transient voltage exceeds the breakdown voltage of the transient voltage suppressor PN diode and the PN rectifier diode is forward biased and conducts current easily. Obviously this circuit can only protect against voltage transients in one direction. A similar circuit using a total of four PN diodes, two transient suppressor diodes and two rectifier diodes can be built to provide transient suppression for voltage transients in either direction.

This change in the circuit to reduce capacitance is widely used throughout the industry with the PN diode rectifier the other key component in addition to the PN transient suppressor diode. There is another type of semiconductor device that also has low capacitance values, but it has never been used in a transient suppressor circuit. This device is known as a PIN diode and it is substantially different form any other diode particularly the PN diode. A PIN diode has a special manufacturing process where the P-type impurity discussed above and the N-type impurity also discussed above do not touch to form the critical PN junction. Instead in the construction of a PIN diode, there is a very high resistivity region labeled the intrinsic (I) region, which separates the P-type impurity from the N-type impurity. Essentially this PIN diode is a two-junction device with a junction between the P-type impurity and the intrinsic region and a second junction between the N-type impurity and the intrinsic region.

The PIN diode was designed and is manufactured for specialized high frequency applications. Because of its unusual structure it has a variable resistance characteristic at high frequency input signals where the resistance can be controlled by the DC forward bias on the PIN diode. Increases in the DC forward bias serve to reduce the variable high frequency resistance of the PIN diode structure. This makes the PIN diode analogous to a MOS transistor where DC bias on the gate of that MOS transistor varies the channel formed between the drain and source of that same MOS transistor and thereby varies the resistance between the source and drain of the that MOS transistor.

The PIN diode is used as an attenuator or a switch in high frequency circuits. Its current-voltage characteristic is markedly different from the PN rectifier diode as shown in the graph below. As can be readily understood, the PIN diode is not an efficient rectifier or other general purpose diode since the intrinsic layer causes a great deal of resistance which in turn causes significant loss of useful power. This power goes into heat and cannot be used by the remainder of any electronic circuit.

The PIN diode has always been utilized as a voltage controlled high frequency variable resistor and is not associated with the classic PN diode.

Another key and very noticeable difference between a PN diode and PIN diode is in the data sheets associated with these devices. A quick review of any data sheets for such devices shows that usually different electrical parameters are specified and for any common parameters, the limits are very different. This is to be expected since PN diodes and PIN diodes are used in different and specific applications.

The ongoing problem is that as electronic circuits get faster, they also get more sensitive to smaller amounts of over voltage and need better protection than is supplied by available voltage transient suppressors. In addition, these advanced, high speed circuits need to have a very low capacitance associated with a voltage transient suppressor since any such capacitance can slow down the performance of that high-speed circuit. There is no commercially available voltage transient suppressor technology that can provide the needed protection for such high-speed circuits.

### SUMMARY OF THE INVENTION

The invention combines a PIN diode with a PN transient voltage suppressor diode to create a unique family of low capacitance transient voltage suppressors. The PIN diode and the PN diode are connected in a back-to-back configuration and housed in the same package thereby forming a transient voltage suppressor that controls positive voltage spikes above a specified threshold. This type of transient voltage suppressor is called a uni-directional device. It is also possible to house two (2) PIN diodes and two (2) PN diodes suitable connected within a single package whereby that combination provides protection for both positive and negative voltage spikes. This type of transient voltage suppressor is called a bi-directional device.

### BRIEF DESCRIPTION OF THE DRAWINGS

FIG. 1 is a cross sectional representation of the prior art PN diode used in transient voltage suppressors.

FIG. 2 is a cross sectional representation of a PIN diode used in the transient voltage suppressor of the invention.

FIG. 3 is a schematic circuit diagram showing a uni-directional transient voltage suppressor of the invention.

FIG. 4 is a schematic circuit diagram showing a bi-directional transient voltage suppressor of the invention.

### DETAILED DESCRIPTION OF THE INVENTION

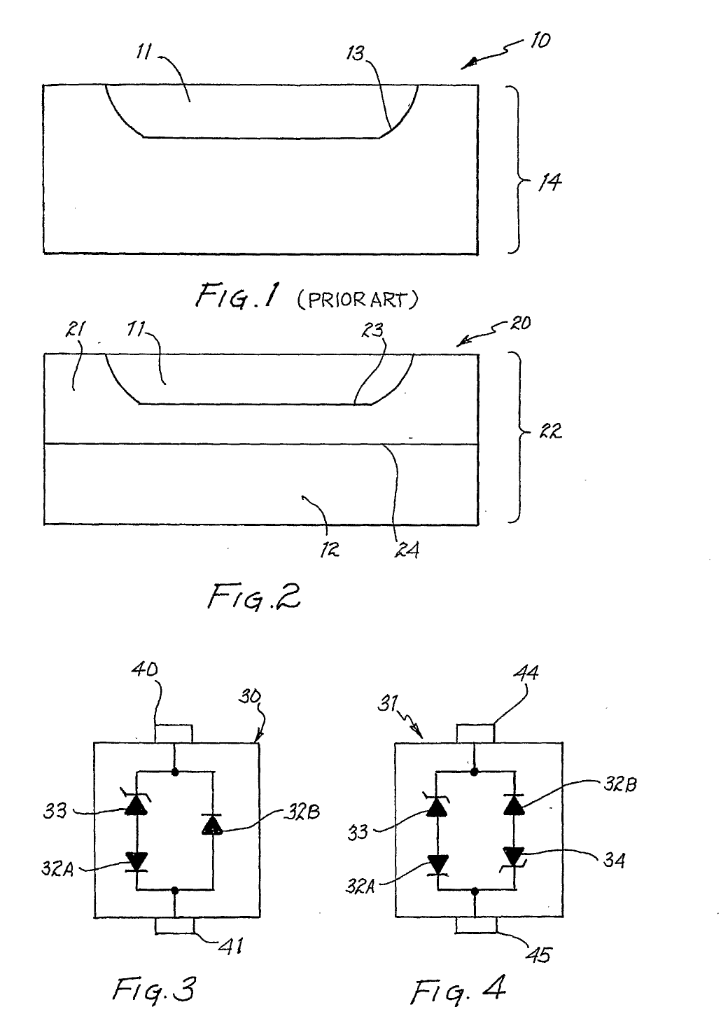

FIG. 1 shows the construction of a PN diode 10 where the P-type region 11 is in direct contact with the N-type region 12 within the semiconductor material 14. This contact is called the PN junction 13 where the junction 13 controls much of the electrical performance of the resulting device. The theory of the PN junction 13 and the manufacturing technology for such PN diodes 10 is well known and well established with many variations possible. The limitation to PN diodes 10 is that the area of such a device must be increased to increase the ability for that PN diode 10 to absorb power, which is critical in transient voltage suppressors. Increasing the area of a PN diode 10 also increases the capacitance associated with that diode.

FIG. 2 shows the more complex structure of a PIN diode 20 where the P-type region 11 is now in direct contact with an intrinsic region 21 while the N-type region 12 is also in contact with the opposite side of that intrinsic region 21. This structure forms a PIN diode 20 in the semiconducting material 22. In this structure there are two junctions, one is the junction 23 between the P-type region 11 and the one side of the intrinsic region 21 and the other junction 24 is between the N-type region 12 and the opposite side of the intrinsic region 21.

The key to achieving the optimum performance of the PIN diode 20 is that intrinsic region 21 which should be as free of impurities as possible making it a region of high resistivity. Advances in semiconductor processing, particularly in the area of material growth have increased the performance of PIN diodes 20. One major area where that increase is noteworthy is the ability to lower the capacitance of the PIN diode 20. While the area of any diode remains critical to the capacitance of that diode, with a PIN diode 20 and the intrinsic region 21, the effect is to space the plates of the capacitor associated with that PIN diode 20 further apart resulting in much lower capacitance values than for a PN diode 10 of the same area. This structure makes the PIN diode 20 most suitable in high-speed transient voltage suppressor devices only.

FIG. 3 shows a schematic for a uni-directional transient voltage suppressor 30 constructed in accordance with the teachings of the present invention. In the uni-directional transient voltage suppressor 30 there are two (2) PIN diodes 32A and 32B and the transient voltage suppressor diode 33 forming the complete uni-directional transient voltage suppressor 30. The reverse biased transient voltage suppressor PN diode 33 is connected as shown to the first terminal 40 and in series with the forward biased PIN diode 32A. The second PIN diode 32B is connected between terminals 40 and 41 in parallel with the series circuit formed by the transient voltage suppressor PN diode 33 and the PIN diode 32A. When installed as specified this device is utilized to protect against positive voltage spikes only while the bi-directional transient voltage suppressor 31 of FIG. 4 can protect against both positive and negative voltage spikes.

The transient voltage suppressor of FIG. 1 may conveniently be referred to as an N base diode wherein the P region is surrounded by and in contact with the N region. This prior art transient voltage suppressor PN diode may also be formed as a P base PN diode. If P base PN diode transient voltage suppressors are chosen, the diode selected for reducing capacitance is a P base low capacitance rectifier device, or commonly referred to as a NIP diode. Such NIP diodes would therefore be used in connection with a P base transient voltage suppressor diodes or any transient voltage suppressor wherein the top junction is N type.

FIG. 4 shows a schematic for a bi-directional transient voltage suppressor 31. The reverse biased transient voltage suppressor PN diode 33 is connected as shown to the first terminal 44 and in series with the forward biased PIN diode 32A. The other terminal of PIN diode 32A is connected to transient voltage suppressor terminal 45. A reverse biased transient voltage suppressor PN diode 34 is connected as shown to the second terminal 45 and in series with the forward biased PIN diode 32B which is connected to transient voltage suppressor terminal 44. The transient voltage suppressor 31 of FIG. 4 is thus a bi-directional transient voltage suppressor that can protect both against positive and negative voltage spikes. These transient voltage suppressor circuits in FIG. 3 and FIG. 4 use PIN diodes 32A and 32B to achieve capacitance values that are a magnitude lower that an be achieved by simply using PN diodes in similar circuits.

To achieve the performance improvement, it is vital that the PIN diodes 32 be constructed with the best possible intrinsic region 21 and also be made with processes that are similar to that use for the transient suppressor diode 33 such that both types of diodes can be easily assembled into packages using high speed assembly equipment. In that way industry standard packages can be used for this new product.

While FIG. 3 and FIG. 4 show only schematics with two connections, it is obvious that arrays of these transient voltage suppressors could also be produced in an appropriate package with more connections.

I claim:

1. A transient voltage suppressor comprising:
(a) a reverse biased transient voltage suppressor PN diode connected to a first terminal;
(b) a low capacitance forward biased diode having a P region separated from an N region by an intrinsic region, connected in series with said PN diode and connected to a second terminal; and
(c) a reverse biased low capacitance diode having a P region separated from an N region by an intrinsic region, connected between said first and second terminals in parallel with the series circuit formed by said reverse biased transient voltage suppressor and said forward biased low capacitance diode.

2. The transient voltage suppressor of claim 1 wherein said PN diode is a P base PN diode.

3. A transient voltage suppressor comprising:
(a) a reverse biased transient voltage suppressor PN diode connected to a first terminal;
(b) a forward biased PIN diode connected in series with said PN diode and connected to a second terminal;
(c) a reverse biased PIN diode connected between said first and second terminals in parallel with the series circuit formed by said reverse biased transient voltage suppressor and said forward biased PN diode;

4. The transient voltage suppressor of claim 3 wherein said PN diode is an N base PN diode.
